(19) United States
(12) Patent Application Publication
(10) Pub. No.: US 2026/0047198 A1
(43) Pub. Date: Feb. 12, 2026

(54) SEMICONDUCTOR DEVICE

(71) Applicant: SAMSUNG ELECTRONICS CO., LTD., Suwon-si (KR)

(72) Inventors: Daihong HUH, Suwon-si (KR); Soomin SON, Suwon-si (KR); Dahye KIM, Suwon-si (KR); Jungtaek KIM, Suwon-si (KR); Cheoljin YUN, Suwon-si (KR); Sangmoon LEE, Suwon-si (KR)

(73) Assignee: SAMSUNG ELECTRONICS CO., LTD., Suwon-si (KR)

(21) Appl. No.: 19/010,997

(22) Filed: Jan. 6, 2025

(30) Foreign Application Priority Data
Aug. 8, 2024 (KR) 10-2024-0106162

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

A semiconductor device may include a lower active pattern extending in a first direction and including a lower channel pattern, and a lower source/drain pattern on a side of the lower channel pattern. The semiconductor device may further include an upper active pattern spaced apart from the lower active pattern in a second direction and including an upper channel pattern, and an upper source/drain pattern on a side of the upper channel pattern. The semiconductor device may further include a first intermediate insulating film between the lower source/drain pattern and the upper source/drain pattern; a through contact extending through the upper source/drain pattern and the first intermediate insulating film in the second direction and electrically connected to the upper source/drain pattern and the lower source/drain pattern; and an upper etch stop film in contact with a portion of a side surface of the through contact.

### CROSS-REFERENCE TO RELATED APPLICATION

This application claims priority to Korean Patent Application No. 10-2024-0106162, filed in the Korean Intellectual Property Office on Aug. 8, 2024, the entire contents of which are hereby incorporated by reference.

### BACKGROUND

### 1. Field

Embodiments of the present disclosure relate to a semiconductor device.

### 2. Description of Related Art

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of the electronic devices are increasing. Accordingly, high-performance characteristics of the semiconductor devices are essentially required, and an integration density of the semiconductor devices is increasing to meet these requirements. Various methods for forming semiconductor devices having excellent performance and improved integration density are being studied.

### SUMMARY

In order to solve one or more problems (e.g., the problems described above and/or other problems not explicitly described herein), embodiments of the present disclosure may provide a semiconductor device with improved reliability and integration density.

According to some embodiments of the present disclosure, a semiconductor device may be provided and include: a lower active pattern extending in a first direction and including: a lower channel pattern; a first lower source/drain pattern on a first side of the lower channel pattern; and a second lower source/drain pattern on a second side of the lower channel pattern, opposite to the first side of the lower channel pattern; an upper active pattern spaced apart from the lower active pattern in a second direction intersecting the first direction and including: an upper channel pattern; a first upper source/drain pattern on a first side of the upper channel pattern; and a second upper source/drain pattern on a second side of the upper channel pattern, opposite to the first side of the upper channel pattern; and a through contact extending through the second upper source/drain pattern in the second direction and electrically connected to the second upper source/drain pattern and the second lower source/drain pattern, wherein the first upper source/drain pattern includes: a first partial growth portion including a 1-1 partial growth portion and a 1-2 partial growth portion spaced apart from each other in the first direction; and an additional growth portion between the 1-1 partial growth portion and the 1-2 partial growth portion, wherein the second upper source/drain pattern includes a second partial growth portion including a 2-1 partial growth portion and a 2-2 partial growth portion spaced apart from each other in the first direction, and wherein at least a portion of a side surface of the through contact extends in the second direction along a profile of the second partial growth portion.

According to some embodiments of the present disclosure, a semiconductor device may be provided and include: a lower active pattern extending in a first direction and including: a lower channel pattern; and a lower source/drain pattern on at least one side of the lower channel pattern; an upper active pattern spaced apart from the lower active pattern in a second direction intersecting the first direction and including: an upper channel pattern; and an upper source/drain pattern on at least one side of the upper channel pattern; a first intermediate insulating film between the lower source/drain pattern and the upper source/drain pattern; a through contact extending through the upper source/drain pattern and the first intermediate insulating film in the second direction and electrically connected to the upper source/drain pattern and the lower source/drain pattern; and an upper etch stop film in contact with at least a portion of a side surface of the through contact.

According to some embodiments of the present disclosure, a semiconductor device may be provided and include: a lower active pattern extending in a first direction and including: a lower channel pattern; a first lower source/drain pattern on a first side of the lower channel pattern; and a second lower source/drain pattern on a second side of the lower channel pattern, opposite to the first side of the lower channel pattern; an upper active pattern spaced apart from the lower active pattern in a second direction intersecting the first direction and including: an upper channel pattern; a first upper source/drain pattern on a first side of the upper channel pattern; and a second upper source/drain pattern on a second side of the upper channel pattern, opposite to the first side of the upper channel pattern; a first intermediate insulating film between the second lower source/drain pattern and the second upper source/drain pattern; a second intermediate insulating film on the first intermediate insulating film; a through contact extending through the second intermediate insulating film, the second upper source/drain pattern, and the first intermediate insulating film in the second direction and electrically connected to the second upper source/drain pattern and the second lower source/drain pattern; and an upper etch stop film in contact with at least a first portion of a side surface of the through contact, wherein the first upper source/drain pattern includes: a first partial growth portion including a 1-1 partial growth portion and a 1-2 partial growth portion spaced apart from each other in the first direction; and an additional growth portion between the 1-1 partial growth portion and the 1-2 partial growth portion, wherein the second upper source/drain pattern includes a second partial growth portion including a 2-1 partial growth portion and a 2-2 partial growth portion spaced apart from each other in the first direction, and wherein at least a second portion of the side surface of the through contact extends in the second direction along a profile of the second partial growth portion.

According to some embodiments of the present disclosure, a simplified patterning process for contact formation may be provided for semiconductor devices by forming a through contact connecting an upper source/drain pattern and a lower source/drain pattern through a process of selectively removing some of the upper source/drain patterns.

According to some embodiments of the present disclosure, the risk of deterioration of the semiconductor device can be reduced by removing an oxide film forming step when forming a trench for the through contact.

### BRIEF DESCRIPTION OF DRAWINGS

The above and other objects, features and advantages of embodiments of the present disclosure will become more apparent to those of ordinary skill in the art by describing in detail example embodiments thereof with reference to the accompanying drawings, in which:

FIG. 1 is an example plan view provided to explain a semiconductor device according to some embodiments;

FIG. 2 is a cross-sectional view taken along a line A-A of FIG. 1;

FIG. 3 is a cross-sectional view taken along a line B-B of FIG. 1;

FIG. 4 is a cross-sectional view taken along a line C-C of FIG. 1;

FIG. 5 is an enlarged view of a region A of FIG. 2;

FIG. 6 is a diagram provided to explain a semiconductor device according to some embodiments;

FIG. 7 is a diagram provided to explain a semiconductor device according to some embodiments;

FIG. 8 is a diagram provided to explain a semiconductor device according to some embodiments; and

FIGS. 9 to 14 are diagrams illustrating intermediate stages, which are provided to explain a method for manufacturing a semiconductor device according to some embodiments.

### DETAILED DESCRIPTION

Hereinafter, a semiconductor device and a method for manufacturing the same according to some non-limiting example embodiments of the present disclosure will be described in detail with reference to the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

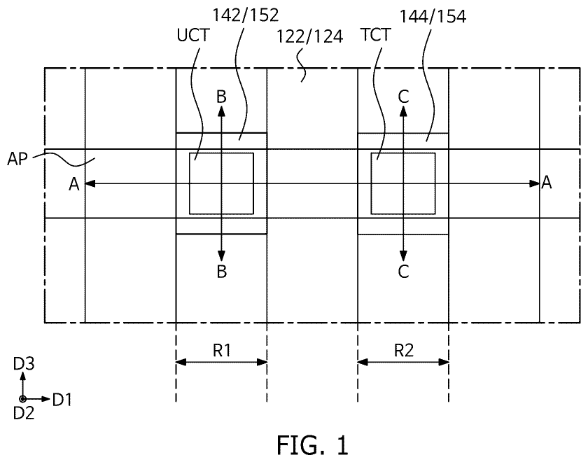

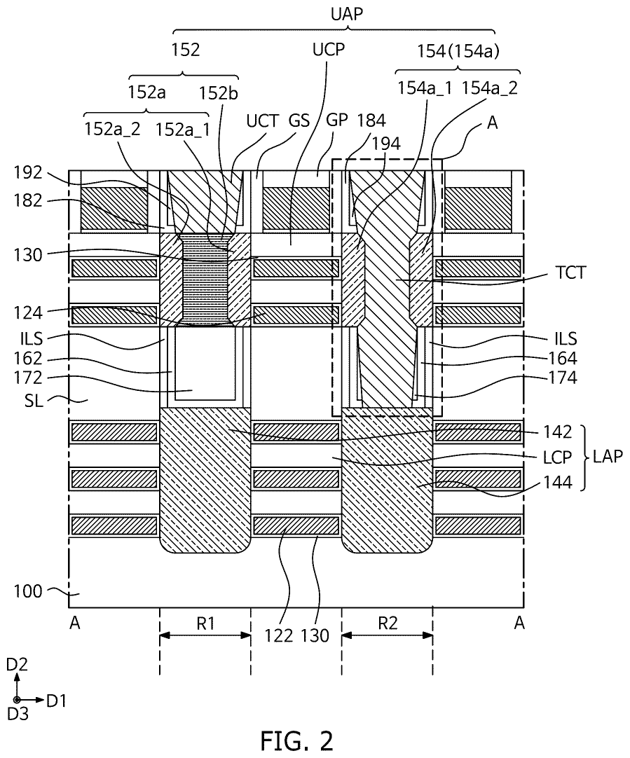

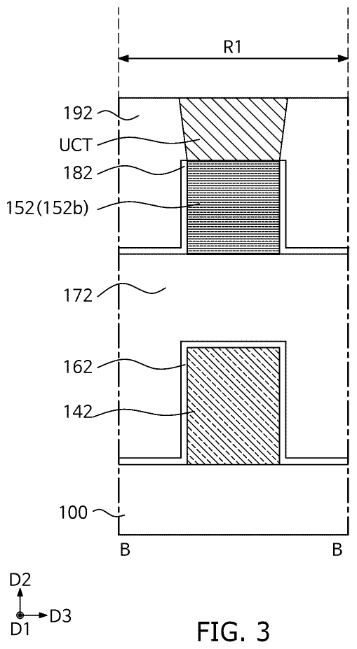

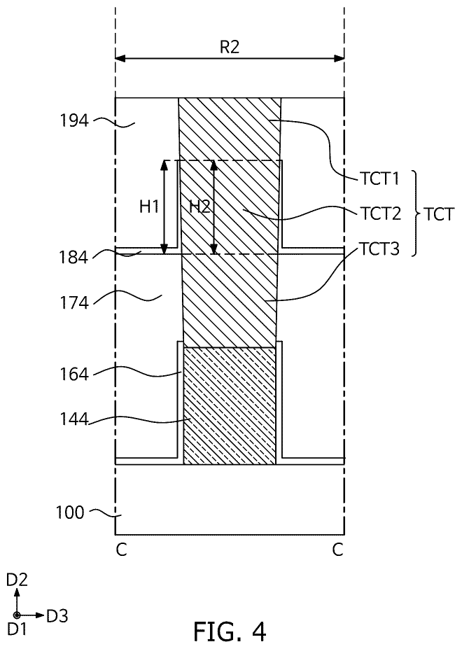

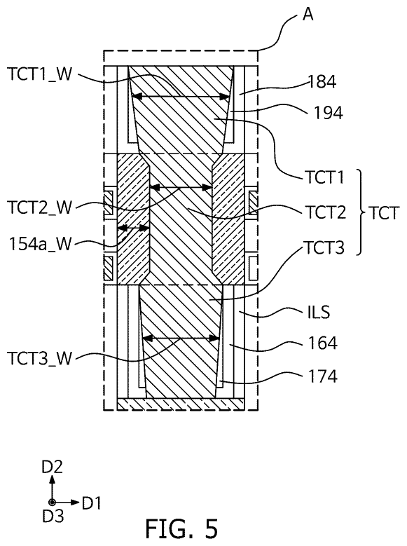

FIG. 1 is an example plan view provided to explain a semiconductor device according to some embodiments. FIG. 2 is a cross-sectional view taken along a line A-A of FIG. 1. FIG. 3 is a cross-sectional view taken along a line B-B of FIG. 1. FIG. 4 is a cross-sectional view taken along a line C-C of FIG. 1. FIG. 5 is an enlarged view of a region A of FIG. 2.

Referring to FIGS. 1 to 5, a semiconductor device according to some embodiments may include a substrate 100, a lower active pattern LAP, an upper active pattern UAP, gate electrodes (e.g., a lower gate electrode 122 and an upper gate electrode 124), a gate insulating film 130, a gate capping pattern GP, a gate spacer GS, lower etch stop films (e.g., a first etch stop film 162 and a second etch stop film 164), first intermediate insulating films (e.g., a 1-1 intermediate insulating film 172 and a 1-2 intermediate insulating film 174), upper etch stop films (e.g., a first upper etch stop film 182 and a second upper etch stop film 184), second intermediate insulating films (e.g., a 2-1 intermediate insulating film 192 and a 2-2 intermediate insulating film 194), an upper source/drain contact UCT, a through contact TCT, etc.

The substrate 100 may be a bulk silicon or a silicon-on-insulator (SOI). On the other hand, the substrate 100 may include silicon germanium (SiGe), silicon germanium on insulator (SGOI), indium antimony, lead tellurium compound, indium arsenic, indium phosphide, gallium arsenic, or gallium antimony, but is not limited thereto.

The lower active pattern LAP may be disposed on the substrate 100. The lower active pattern LAP may extend in a first direction D1. The lower active pattern LAP may include a lower channel pattern LCP, a first lower source/drain pattern 142 disposed on one side of the lower channel pattern LCP, and a second lower source/drain pattern 144 disposed on another side of the lower channel pattern LCP. In some embodiments, the lower channel pattern LCP may include a plurality of sheet patterns. For example, the lower active pattern LAP may include a plurality of lower channel patterns LCP stacked in a second direction D2 intersecting (e.g., perpendicular to) the first direction D1, the first lower source/drain pattern 142 disposed on one side of the plurality of lower channel patterns LCP, and the second lower source/drain pattern 144 disposed on the other side of the plurality of lower channel patterns LCP.

The upper active pattern UAP may be disposed on the lower active pattern LAP. The upper active pattern UAP may extend in the first direction D1. The upper active pattern UAP may include an upper channel pattern UCP, a first upper source/drain pattern 152 disposed on one side of the upper channel pattern UCP, and a second upper source/drain pattern 154 disposed on another side of the upper channel pattern UCP. In some embodiments, the upper channel pattern UCP may include a plurality of sheet patterns. For example, the upper active pattern UAP may include a plurality of upper channel patterns UCP stacked in the second direction D2, the first upper source/drain pattern 152 disposed on one side of the plurality of upper channel patterns UCP, and the second upper source/drain pattern 154 disposed on the other side of the plurality of upper channel patterns UCP.

According to some embodiments, each of the lower channel pattern LCP and the upper channel pattern UCP includes two sheet patterns. However, embodiments are not limited thereto. According to some embodiments, each of the lower channel pattern LCP and the upper channel pattern UCP may include one or three or more sheet patterns. In addition, the number of sheet patterns of the lower channel pattern LCP and the number of sheet patterns of the upper channel pattern UCP may be different from each other. For example, the number of sheet patterns of the lower channel pattern LCP may be three, and the number of sheet patterns of the upper channel pattern UCP may be two.

Each of the lower channel pattern LCP and the upper channel pattern UCP may include one from among an element semiconductor material such as silicon (Si) or silicon germanium (SiGe), a group IV-IV compound semiconductor, and a group III-V compound semiconductor.

For example, the group IV-IV compound semiconductor may be a binary compound or a ternary compound including at least two or more from among carbon (C), silicon (Si), germanium (Ge), tin (Sn), and a compound doped with a group IV element.

For example, the group III-V compound semiconductor may be one from among a binary compound, a ternary compound, and a quaternary compound formed by a combination of at least one from among aluminum (Al), gallium (Ga), and indium (In) as a group III element and one from among phosphorus (P), arsenic (As), and antimony (Sb) as a group V element.

The upper channel pattern UCP may be disposed to be spaced apart from the lower channel pattern LCP in the second direction D2. The upper channel pattern UCP may overlap with the lower channel pattern LCP in the second direction D2. A level isolation insulating film SL may be disposed between the upper channel pattern UCP and the lower channel pattern LCP.

In some embodiments, the lower active pattern LAP may include lower patterns spaced apart from each other in a third direction D3 and extending in the first direction D1 on the substrate 100. The lower channel pattern LCP of the lower active pattern LAP may be disposed on the lower pattern.

In some embodiments, the substrate 100 may include an insulating material. For example, the substrate 100 may be an insulating substrate. According to some embodiments, the semiconductor device according to some embodiments may further include a lower gate contact formed through the substrate 100 or the lower pattern.

The gate electrodes (e.g., the lower gate electrode 122 and the upper gate electrode 124) may surround the lower channel pattern LCP and the upper channel pattern UCP. The gate electrodes (e.g., the lower gate electrode 122 and the upper gate electrode 124) may extend in the third direction D3 intersecting (e.g., perpendicular to) the first direction D1 and the second direction D2. In some embodiments, the gate electrodes may include the lower gate electrode 122 surrounding the lower channel pattern LCP and the upper gate electrode 124 surrounding the upper channel pattern UCP.

The gate electrodes (e.g., the lower gate electrode 122 and the upper gate electrode 124) may include at least one from among a metal, a metal alloy, a conductive metal nitride, a metal silicide, a doped semiconductor material, a conductive metal oxide, and a conductive metal oxynitride. For example, the gate electrodes (e.g., the lower gate electrode 122 and the upper gate electrode 124) may include at least one from among titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto.

It is illustrated that the gate electrodes (e.g., the lower gate electrode 122 and the upper gate electrode 124) include single films, but embodiments are not limited thereto. For example, the gate electrodes (e.g., the lower gate electrode 122 and the upper gate electrode 124) may include a work function control film that controls work functions and a filling conductive film that fills a space formed by the work function control film. The work function control film may include, for example, at least one from among titanium nitride (TiN), tantalum carbide (TaC), tantalum nitride (TaN), titanium aluminum carbide (TiAlC), titanium carbide (TiC), and a combination thereof. For example, the filling conductive film may include tungsten (W) or aluminum (Al).

In some embodiments, the lower gate electrode 122 and the upper gate electrode 124 may include different materials from each other. Accordingly, an interface between the lower gate electrode 122 and the upper gate electrode 124 may be identified on one end surface of the semiconductor device according to some embodiments. However, embodiments are not limited thereto, and even when the lower gate electrode 122 and the upper gate electrode 124 include different materials from each other, the interface may not necessarily appear between the lower gate electrode 122 and the upper gate electrode 124.

In some embodiments, the lower gate electrode 122 and the upper gate electrode 124 may include the same material. In this case, the interface may not appear between the lower gate electrode 122 and the upper gate electrode 124.

The gate insulating film 130 may be disposed on the gate electrodes (e.g., the lower gate electrode 122 and the upper gate electrode 124). For example, the gate insulating film 130 may be disposed between the lower gate electrode 122 and the lower channel pattern LCP, and between the upper gate electrode 124 and the upper channel pattern UCP. Further, the gate insulating film 130 may be disposed between the lower gate electrode 122 and the first lower source/drain pattern 142, and between the lower gate electrode 122 and the second lower source/drain pattern 144, respectively. Further, the gate insulating film 130 may be disposed between the upper gate electrode 124 and the first upper source/drain pattern 152, and between the upper gate electrode 124 and the second upper source/drain pattern 154, respectively. Although the gate insulating film 130 is illustrated as a single film, embodiments are not limited thereto. According to some embodiments, the gate insulating film 130 may include a plurality of films. For example, the gate insulating film 130 may include a high-k insulating film and an interfacial insulating film.

The gate insulating film 130 may include, for example, silicon oxide, silicon oxynitride, silicon nitride, or a high-k material having a greater dielectric constant than silicon oxide. For example, the high-k material may include one or more from among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate capping pattern GP may be disposed on an upper surface of the upper gate electrode 124. For example, the gate capping pattern GP may cover the upper surface of the upper gate electrode 124. The gate capping pattern GP may be disposed between the gate spacers GS. The side surface of the gate capping pattern GP may be in contact with the gate spacer GS.

For example, the gate capping pattern GP may include at least one from among silicon nitride (SiN), silicon oxynitride (SiON), silicon carbon nitride (SiCN), silicon oxycarbonitride (SiOCN), and a combination thereof. The gate capping pattern GP may include a material having etch selectivity with respect to the second intermediate insulating films (e.g., the 2-1 intermediate insulating film 192 and the 2-2 intermediate insulating film 194).

The gate spacers GS may be disposed on a side surface of an upper region of the upper gate electrode 124 and on a side surface of the gate capping pattern GP. The upper region of the upper gate electrode 124 may be disposed on an uppermost channel pattern of the upper channel pattern UCL. For example, the gate spacers GS may extend along the side surface of the upper region of the upper gate electrode 124 and the side surface of the gate capping pattern GP.

For example, the gate spacer GS may include at least one from among silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and a combination thereof. Although it is illustrated that the gate spacer GS is a single film, it is only for convenience of explanation, and embodiments are not limited thereto.

According to some embodiments, a gate contact may be disposed on the gate capping pattern GP. The gate contact may be formed through the gate capping pattern GP in the second direction D2 and electrically connected to the upper gate electrode 124. The gate contact may include a conductive material.

The substrate 100 may include a first region R1 and a second region R2. The first lower source/drain pattern 142 and the first upper source/drain pattern 152 may be disposed on the first region R1. For example, the first lower source/drain pattern 142 and the first upper source/drain pattern 152 spaced apart from the first lower source/drain pattern 142 in the second direction D2 may be disposed on the first region R1. The first region R1 may represent a region on which a single source/drain contact that electrically connects both the first lower source/drain pattern 142 and the first upper source/drain pattern 152 is not disposed. That is, the first lower source/drain pattern 142 and the first upper source/drain pattern 152 may be electrically connected to separate source/drain contacts, respectively. For example, the first upper source/drain pattern 152 may be electrically connected to the upper source/drain contact UCT. Further, according to some embodiments, the first lower source/drain pattern 142 may be electrically connected to a separate source/drain contact.

The second lower source/drain pattern 144 and the second upper source/drain pattern 154 may be disposed on the second region R2. For example, the second lower source/drain pattern 144 and the second upper source/drain pattern 154 spaced apart from the second lower source/drain pattern 144 in the second direction D2 may be disposed on the second region R2. The second region R2 may represent a region where a source/drain contact (e.g., the through contact TCT) that electrically connects the second lower source/drain pattern 144 and the second upper source/drain pattern 154 at the same time is disposed. That is, the second lower source/drain pattern 144 and the second upper source/drain pattern 154 may be electrically connected to each other through the through contact TCT.

The first region R1 and/or the second region R2 may be disposed adjacent to each other in succession with a channel pattern interposed therebetween. For example, FIG. 2 illustrates the semiconductor device in which only the first region R1 and the second region R2 are disposed adjacent to each other, but embodiments are not limited thereto. In the semiconductor device according to some embodiments, another first region R1 may be disposed adjacent to the first region R1, and another second region R2 may be disposed adjacent to the second region R2. Hereinbelow, for convenience of explanation, an embodiments in which the first region R1 and the second region R2 are disposed adjacent to each other will be described.

The lower source/drain patterns (e.g., the first lower source/drain pattern 142 and the second lower source/drain pattern 144) may be disposed on at least one side of the lower channel pattern LCP. For example, the first lower source/drain pattern 142 may be disposed on one side of the lower channel pattern LCP. The second lower source/drain pattern 144 may be disposed on another side of the lower channel pattern LCP. That is, the lower channel pattern LCP may be disposed between the first lower source/drain pattern 142 and the second lower source/drain pattern 144. The first lower source/drain pattern 142 may face the second lower source/drain pattern 144 in the first direction D1 with the lower channel pattern LCP therebetween.

The lower source/drain patterns (e.g., the first lower source/drain pattern 142 and the second lower source/drain pattern 144) may include an epitaxial pattern. The lower source/drain patterns (e.g., the first lower source/drain pattern 142 and the second lower source/drain pattern 144) may include a semiconductor material. For example, the lower source/drain patterns (e.g., the first lower source/drain pattern 142 and the second lower source/drain pattern 144) may include an element semiconductor material such as silicon (Si) or germanium (Ge). In addition, the lower source/drain patterns (e.g., the first lower source/drain pattern 142 and the second lower source/drain pattern 144) may include, for example, a binary compound or a ternary compound including at least two or more from among carbon (C), silicon (Si), germanium (Ge), tin (Sn), and a compound of these doped with a group IV element. For example, the lower source/drain patterns (e.g., the first lower source/drain pattern 142 and the second lower source/drain pattern 144) may include silicon (Si), silicon-germanium (SiGe), germanium (Ge), silicon carbide (SiC), etc., but is not limited thereto.

Although it is illustrated that the lower source/drain patterns (e.g., the first lower source/drain pattern 142 and the second lower source/drain pattern 144) are single films, embodiments are not limited thereto, and the lower source/drain patterns (e.g., the first lower source/drain pattern 142 and the second lower source/drain pattern 144) may include a plurality of films. If the lower source/drain patterns (e.g., the first lower source/drain pattern 142 and the second lower source/drain pattern 144) include a plurality of films, each of the plurality of films may be a semiconductor material having a different dopant concentration.

The upper source/drain patterns (e.g., the first upper source/drain pattern 152 and the second upper source/drain pattern 154) may be disposed on at least one side of the lower channel pattern LCP. For example, the first upper source/drain pattern 152 may be disposed on one side of the upper channel pattern UCP. The second upper source/drain pattern 154 may be disposed on the other side of the upper channel pattern UCP. That is, the upper channel pattern UCP may be disposed between the first upper source/drain pattern 152 and the second upper source/drain pattern 154. The first upper source/drain pattern 152 may face the second upper source/drain pattern 154 in the first direction D1 with respect to the upper channel pattern UCP.

The upper source/drain patterns (e.g., the first upper source/drain pattern 152 and the second upper source/drain pattern 154) may include an epitaxial pattern. The upper source/drain patterns (e.g., the first upper source/drain pattern 152 and the second upper source/drain pattern 154) may include a semiconductor material. Description of the material of the upper source/drain patterns (e.g., the first upper source/drain pattern 152 and the second upper source/drain pattern 154) may be the same as or similar to description of the lower source/drain patterns (e.g., the first lower source/drain pattern 142 and the second lower source/drain pattern 144).

The lower source/drain patterns (e.g., the first lower source/drain pattern 142 and the second lower source/drain pattern 144) and the upper source/drain patterns (e.g., the first upper source/drain pattern 152 and the second upper source/drain pattern 154) may have opposite conductivity types. For example, at least one of the first lower source/drain pattern 142 or the second lower source/drain pattern 144 may have a p-type conductivity. Further, at least one of the first upper source/drain pattern 152 or the second upper source/drain pattern 154 may have an n-type conductivity. According to some embodiments, the lower source/drain patterns (e.g., the first lower source/drain pattern 142 and the second lower source/drain pattern 144) and the upper source/drain patterns (e.g., the first upper source/drain pattern 152 and the second upper source/drain pattern 154) may have the same conductivity as each other.

In some embodiments, the first upper source/drain pattern 152 may include a first partial growth portion 152a and a first additional growth portion 152b. The first partial growth portion 152a may be disposed at both ends of the first upper source/drain pattern 152 in the first direction D1. For example, the first partial growth portion 152a may include a 1-1partial growth portion 152a_1 and a 1-2 partial growth portion 152a_2 spaced apart from each other in the first direction D1. The 1-1 partial growth portion 152a_1 and the 1-2 partial growth portion 152a_2 may be disposed on side surfaces of respective ones of the upper channel pattern UCP and the upper gate electrode 124. The first additional growth portion 152b may be disposed between the 1-1 partial growth portion 152a_1 and the 1-2 partial growth portion 152a_2. In some embodiments, an outer side surface of the first additional growth portion 152b in contact with the first partial growth portion 152a may extend along a profile of the first partial growth portion 152a.

The first partial growth portion 152a and the first additional growth portion 152b may include different materials from each other. In some embodiments, the first partial growth portion 152a may include a first material, and the first additional growth portion 152b may include a second material having etch selectivity with respect to the first material. For example, the first material may include n-type doped silicon (Si). The second material may include n-type doped silicon germanium (SiGe). For example, the second material may include phosphorus-doped silicon germanium (SiGe; P). However, embodiments are not limited thereto.

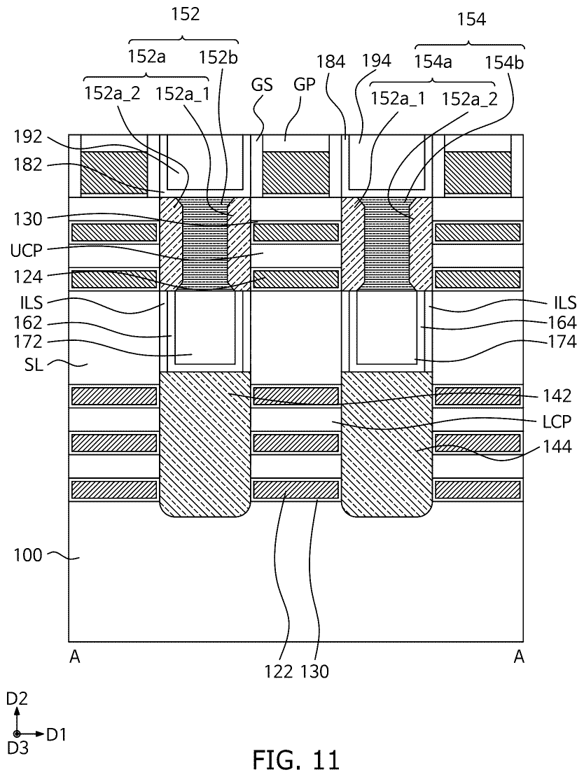

In some embodiments, the second upper source/drain pattern 154 may include a second partial growth portion 154a. The second partial growth portion 154a may be disposed at both ends of the second upper source/drain pattern 154 in the first direction D1. For example, the second partial growth portion 154a may include a 2-1 partial growth portion 154a_1 and a 2-2 partial growth portion 154a_2 spaced apart from each other in the first direction D1. The 2-1 partial growth portion 154a_1 and the 2-2 partial growth portion 154a_2 may be disposed on side surfaces of respective ones of the upper channel pattern UCP and the upper gate electrode 124. When the through contact TCT is formed, a second additional growth portion (e.g., second additional growth portion 154b of FIG. 11) of the second upper source/drain pattern 154 may be removed by selective etching. Accordingly, the second upper source/drain pattern 154 may not include the second additional growth portion including the second material. However, embodiments are not limited thereto. The second upper source/drain pattern 154 may include a portion of the second additional growth portion that remains without being removed by selective etching.

The lower etch stop films (e.g., the first lower etch stop film 162 and the second lower etch stop film 164) may be disposed on the lower source/drain patterns (e.g., the first lower source/drain pattern 142 and the second lower source/drain pattern 144). For example, the first lower etch stop film 162 may be disposed on the first lower source/drain pattern 142. The second lower etch stop film 164 may be disposed on the second lower source/drain pattern 144. In some embodiments, the lower etch stop films (e.g., the first lower etch stop film 162 and the second lower etch stop film 164) may be disposed on a side surface of the level isolation insulating film SL. For example, the lower etch stop films (e.g., the first lower etch stop film 162 and the second lower etch stop film 164) may extend from both ends in the first direction D1 of an upper surface of the lower source/drain patterns (e.g., the first lower source/drain pattern 142 and the second lower source/drain pattern 144) to a lower surface of the upper source/drain patterns (e.g., the first upper source/drain pattern 152 and the second upper source/drain pattern 154) in the second direction D2.

In some embodiments, an interlayer spacer ILS may be disposed between the lower source/drain patterns (e.g., the first lower source/drain pattern 142 and the second lower source/drain pattern 144) and the upper source/drain patterns (e.g., the first upper source/drain pattern 152 and the second upper source/drain pattern 154). The interlayer spacer ILS may be disposed between the lower etch stop films (e.g., the first lower etch stop film 162 and the second lower etch stop film 164) and the level isolation insulating film SL.

Upper etch stop films (e.g., the first upper etch stop film 182 and the second upper etch stop film 184) may be disposed on the upper source/drain patterns (e.g., the first upper source/drain pattern 152 and the second upper source/drain pattern 154). For example, the first upper etch stop film 182 may be disposed on the first upper source/drain pattern 152. The second upper etch stop film 184 may be disposed on the second upper source/drain pattern 154.

For example, each of the lower etch stop films (e.g., the first lower etch stop film 162 and the second lower etch stop film 164) and the upper etch stop films (e.g., the first upper etch stop film 182 and the second upper etch stop film 184) may include at least one from among silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and a combination thereof.

The first intermediate insulating films (e.g., the 1-1 intermediate insulating film 172 and the 1-2 intermediate insulating film 174) may be disposed between the lower source/drain patterns (e.g., the first lower source/drain pattern 142 and the second lower source/drain pattern 144) and the upper source/drain patterns (e.g., the first upper source/drain pattern 152 and the second upper source/drain pattern 154). The first intermediate insulating films (e.g., the 1-1 intermediate insulating film 172 and the 1-2 intermediate insulating film 174) may cover the lower source/drain patterns (e.g., the first lower source/drain pattern 142 and the second lower source/drain pattern 144). For example, the 1-1 intermediate insulating film 172 may be disposed between the first lower source/drain pattern 142 and the first upper source/drain pattern 152. The 1-1 intermediate insulating film 172 may cover the first lower source/drain pattern 142. Further, the 1-2 intermediate insulating film 174 may be disposed between the second lower source/drain pattern 144 and the second upper source/drain pattern 154. The 1-2 intermediate insulating film 174 may cover the second lower source/drain pattern 144.

For example, the first intermediate insulating films (e.g., the 1-1 intermediate insulating film 172 and the 1-2 intermediate insulating film 174) may include at least one from among silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The second intermediate insulating films (e.g., the 2-1 intermediate insulating film 192 and the 2-2 intermediate insulating film 194) may be disposed on the first intermediate insulating films (e.g., the 1-1 intermediate insulating film 172 and the 1-2 intermediate insulating film 174). The second intermediate insulating films (e.g., the 2-1 intermediate insulating film 192 and the 2-2 intermediate insulating film 194) may cover the upper source/drain patterns (e.g., the first upper source/drain pattern 152 and the second upper source/drain pattern 154). For example, the 2-1 intermediate insulating film 192 may be disposed on the first upper source/drain pattern 152. Further, the 2-2 intermediate insulating film 194 may be disposed on the second upper source/drain pattern 154. The second intermediate insulating films (e.g., the 2-1 intermediate insulating film 192 and the 2-2 intermediate insulating film 194) may surround a sidewall of the gate spacer GS and a sidewall of the gate capping pattern GP. For example, the second intermediate insulating films (e.g., the 2-1 intermediate insulating film 192 and the 2-2 intermediate insulating film 194) may include at least one from among silicon oxide (SiO), silicon nitride (SiN), silicon oxynitride (SiON), and a low-k material. The low-k material may include a material described with respect to the first intermediate insulating films (e.g., the 1-1 intermediate insulating film 172 and the 1-2 intermediate insulating film 174), and will not be redundantly described below.

In some embodiments, the upper etch stop films (e.g., the first upper etch stop film 182 and the second upper etch stop film 184) may be disposed between the second intermediate insulating films (e.g., the 2-1 intermediate insulating film 192 and the 2-2 intermediate insulating film 194) and the first intermediate insulating films (e.g., the 1-1 intermediate insulating film 172 and the 1-2 intermediate insulating film 174). In this case, the upper etch stop films (e.g., the first upper etch stop film 182 and the second upper etch stop film 184) may be disposed in a direction parallel to one surface of the substrate 100 (e.g., in the first direction D1 and the third direction D3) along an interface between the second intermediate insulating films (e.g., the 2-1 intermediate insulating film 192 and the 2-2 intermediate insulating film 194) and the first intermediate insulating films (e.g., the 1-1 intermediate insulating film 172 and the 1-2 intermediate insulating film 174).

In some embodiments, the second intermediate insulating films (e.g., the 2-1 intermediate insulating film 192 and the 2-2 intermediate insulating film 194) and the first intermediate insulating films (e.g., the 1-1 intermediate insulating film 172 and the 1-2 intermediate insulating film 174) may be integrally formed. In this case, the interface between the second intermediate insulating films (e.g., the 2-1 intermediate insulating film 192 and the 2-2 intermediate insulating film 194) and the first intermediate insulating films (e.g., the 1-1 intermediate insulating film 172 and the 1-2 intermediate insulating film 174) may not appear.

An upper source/drain contact UCT may be disposed on the first upper source/drain pattern 152. The upper source/drain contact UCT may include a conductive material. The upper source/drain contact UCT may be electrically connected to the first upper source/drain pattern 152. The upper source/drain contact UCT may be formed through the 2-1 intermediate insulating film 192 and the first upper etch stop film 182.

For example, the upper source/drain contact UCT may be disposed on an upper surface of the first upper source/drain pattern 152. Although it is illustrated that the upper surface of the first upper source/drain pattern 152 and a lower surface of the upper source/drain contact UCT are on a same plane as each other, embodiments are not limited thereto. For example, a portion of the upper source/drain contact UCT may be formed through the upper surface of the first upper source/drain pattern 152. In this case, a vertical level of the lower surface of the upper source/drain contact UCT may be located between vertical levels of the upper surface and the lower surface of the first upper source/drain pattern 152.

The through contact TCT may be disposed on the second lower source/drain pattern 144 and the second upper source/drain pattern 154. The through contact TCT may extend through the second upper source/drain pattern 154 in the second direction D2. Specifically, the through contact TCT may extend through the 2-2 intermediate insulating film 194, the second upper source/drain pattern 154, and the 1-2 intermediate insulating film 174 in the second direction D2. The through contact TCT may be electrically connected to the second lower source/drain pattern 144 and the second upper source/drain pattern 154.

In some embodiments, the second upper etch stop film 184 may be in contact with at least a portion of a side surface of the through contact TCT. When the through contact TCT is formed, the second additional growth portion (e.g., second additional growth portion second additional growth portion 154b of FIG. 11) of the second upper source/drain pattern 154 may be removed by selective etching. In this case, the second upper etch stop film 184 disposed on both side surfaces of the second additional growth portion in the third direction D3 may remain after the second additional growth portion is removed. Accordingly, as illustrated in FIG. 4, the second upper etch stop film 184 may be disposed on both side surfaces in the third direction D3 of the through contact TCT formed by filling a space from which the second additional growth portion has been removed.

In some embodiments, the vertical level of the uppermost end (or upper surface) of the second upper etch stop film 184 may be less than or equal to a vertical level of the uppermost end (or upper surface) of the second upper source/drain pattern 154. For example, a height H1 of the second upper etch stop film 184 may be equal to a height H2 of the second partial growth portion 154a of the second upper source/drain pattern 154 or less than the height H2 of the second partial growth portion 154a.

In some embodiments, at least a portion of the side surface of the through contact TCT may extend in the second direction D2 along a profile of the second partial growth portion 154a. For example, the through contact TCT may be formed by filling a space, from which the second additional growth portion (e.g., second additional growth portion 154b of FIG. 11) of the second upper source/drain pattern 154 has been removed, with a conductive material. Accordingly, shapes of side surfaces of the through contact TCT and the second partial growth portion 154a may correspond to each other in a direction in which the through contact TCT and the second partial growth portion 154a face each other. That is, the shape of the side surface of the through contact TCT in the first direction D1 may correspond to the shape of the side surface of the second partial growth portion 154a in the first direction D1.

In some embodiments, the through contact TCT may include a first contact region TCT1, a second contact region TCT2, and a third contact region TCT3.

Referring to FIG. 5, the first contact region TCT1 may be disposed above the second contact region TCT2, and the third contact region TCT3 may be disposed below the second contact region TCT2. The first contact region TCT1, the second contact region TCT2, and the third contact region TCT3 may overlap in the second direction D2. The through contact TCT may have a cross section in which a thickness of the second contact region TCT2, located in the center of the through contact, is thinner than the thicknesses of the first contact region TCT1 and the third contact region TCT3 located thereabove and therebelow with respect to the second direction D2, respectively.

Specifically, the first contact region TCT1 may be formed through an upper surface of the 2-2 intermediate insulating film 194, and disposed on a vertical level higher than a vertical level of the second upper source/drain pattern 154. In some embodiments, a width TCT1_W of the first contact region TCT1 in the first direction may decrease towards a lower end of the first contact region TCT1.

The second contact region TCT2 may be disposed on the same vertical level as the vertical level of the second upper source/drain pattern 154. In some embodiments, the second contact region TCT2 may be in contact with the second upper source/drain pattern 154. For example, referring to FIGS. 2 and 5, the second upper source/drain pattern 154 may be disposed on a side surface of the second contact region TCT2 in the first direction D1. Further, the second contact region TCT2 may be in contact with the second upper etch stop film 184. For example, referring to FIG. 4, the second upper etch stop film 184 may be disposed on a side surface of the second contact region TCT2 in the third direction D3.

The second contact region TCT2 may be disposed on the same vertical level as that the vertical level of the second partial growth portion 154a. In some embodiments, a thickness 154a_W of the second partial growth portion 154a in the first direction D1 may decrease towards at least one from among an upper end and a lower end of the second partial growth portion 154a. A width TCT2_W of the second contact region TCT2 in the first direction D1 may increase towards at least one from among the upper end and the lower end of the second partial growth portion 154a. For example, referring to FIG. 5, the thickness 154a_W of the second partial growth portion 154a in the first direction D1 may decrease towards the upper end of the second partial growth portion 154a. In this case, the width TCT2_W of the second contact region TCT2 in the first direction D1 may increase towards the upper end of the second partial growth portion 154a. Further, the thickness 154a_W of the second partial growth portion 154a in the first direction D1 may decrease towards the lower end of the second partial growth portion 154a. In this case, the width TCT2_W of the second contact region TCT2 in the first direction D1 may increase towards the lower end of the second partial growth portion 154a.

The third contact region TCT3 may be in contact with the second lower source/drain pattern 144, and may be disposed on a lower vertical level than the vertical level of the second upper source/drain pattern 154a. A width TCT3_W of the third contact region TCT3 in the first direction D1 may decrease towards the lower end of the third contact region TCT3.

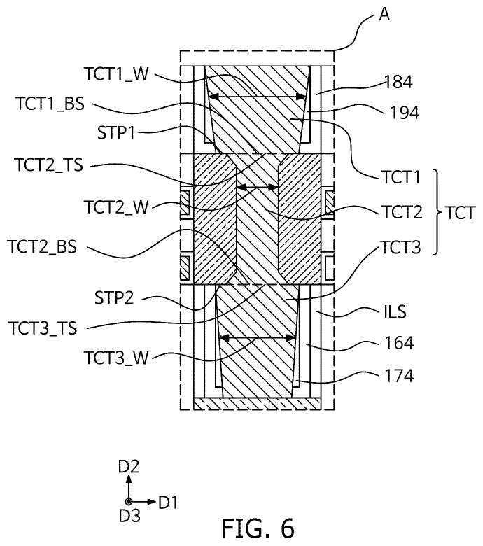

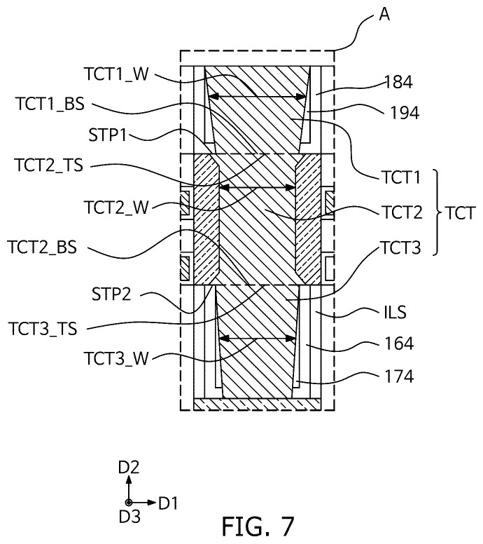

FIGS. 6 and 7 are diagrams provided to explain a semiconductor device according to some embodiments. FIGS. 6 and 7 are enlarged views of the region A of FIG. 2. The semiconductor devices of FIGS. 6 and 7 may be substantially the same as those described above with reference to FIGS. 1 to 5 except for the shape of the through contact TCT. For convenience of explanation, different configurations from those described above in FIGS. 1 to 5 will be mainly described.

The through contact TCT may include a first stepped surface STP1. The first stepped surface STP1 may be formed by a difference between a width in the first direction D1 of a lower surface TCT1_BS of the first contact region TCT1 and a width in the first direction D1 of an upper surface TCT2_TS of the second contact region TCT2. For example, referring to FIG. 6, the first stepped surface STP1 may extend from a sidewall of the first contact region TCT1 towards the interior the first contact region TCT1. In another example, referring to FIG. 7, the first stepped surface STP1 may extend from a sidewall of the first contact region TCT1 towards the exterior of the first contact region TCT1.

The through contact TCT may include a second stepped surface STP2. The second stepped surface STP2 may be formed by a difference between a width in the first direction D1 of a lower surface TCT2_BS of the second contact region TCT2 and a width in the first direction D1 of an upper surface TCT3_TS of the third contact region TCT3. For example, referring to FIG. 6, the second stepped surface STP1 may extend from a sidewall of the third contact region TCT3 towards the interior of the third contact region TCT3. In another example, referring to FIG. 7, the second stepped surface STP1 may extend from a sidewall of the third contact region TCT3 towards the exterior of the third contact region TCT3.

In FIGS. 6 and 7, the first stepped surface STP1 and the second stepped surface STP2 are illustrated as being parallel to the first direction D1, but embodiments are not limited to thereto. The first stepped surface STP1 and the second stepped surface STP2 may include a slope and/or a curvature. In addition, only one of the first stepped surface STP1 and the second stepped surface STP2 may be formed.

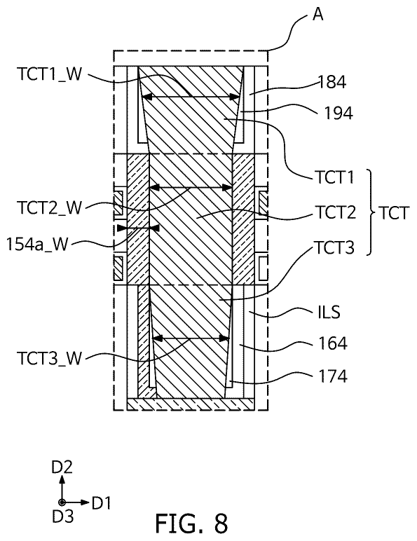

FIG. 8 is a diagram provided to explain a semiconductor device according to some embodiments. FIG. 8 is an enlarged view of the region A of FIG. 2. The semiconductor device of FIG. 8 may be substantially the same as the semiconductor device described with reference to FIGS. 1 to 7 except for the shape of the through contact TCT. For convenience of description, different configurations from those described above with reference to FIGS. 1 to 7 will be mainly described.

In some embodiments, the thickness 154a_W of the second partial growth portion 154a in the first direction D1 may be constant. For example, the thickness 154a_W of the second partial growth portion 154a in the first direction D1 may be substantially the same from the vertical level of the upper end of the second partial growth portion 154a to the vertical level of the lower end. In this case, the width TCT2_W of the second contact region TCT2 in the first direction D1 may be constant. For example, the width TCT2_W of the second contact region TCT2 in the first direction D1 may be substantially the same from the vertical level of the upper end of the second contact region TCT2 to the vertical level of the lower end.

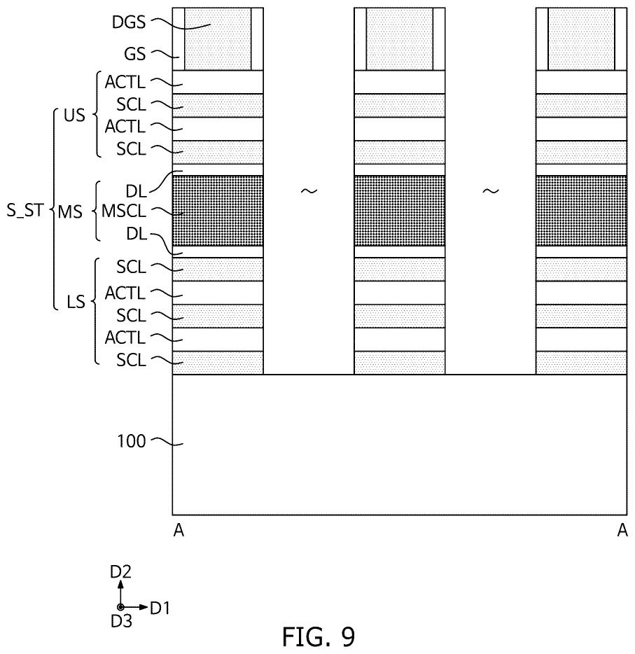

FIGS. 9 to 14 are diagrams illustrating intermediate stages, which are provided to explain a method for manufacturing a semiconductor device according to some embodiments. For reference, FIGS. 9 to 14 are diagrams corresponding to a cross-sectional view taken along the line A-A of FIG. 1.

Referring to FIG. 9, the method for manufacturing the semiconductor device according to some embodiments may include forming a stack structure S_ST, that is patterned, on the substrate 100.

The substrate 100 may be a silicon substrate, or may include other materials such as silicon germanium (SiGe), silicon germanium on insulator (SGOI), indium antimony, lead tellurium compound, indium arsenic, indium phosphide, gallium arsenic, or gallium antimony, but is not limited thereto.

The stack structure S_ST may be formed on the substrate 100. The stack structure S_ST may include a sacrificial semiconductor layer SCL and an active semiconductor layer ACTL which are alternately stacked. As illustrated, the stack structure S_ST may include an upper stack structure US, an intermediate stack structure MS, and a lower stack structure LS. The upper stack structure US may be defined as a stack structure of the active semiconductor layer ACTL and the sacrificial semiconductor layer SCL disposed above the intermediate stack structure MS. The lower stack structure LS may be defined as a stack structure of the active semiconductor layer ACTL and the sacrificial semiconductor layer SCL disposed below the intermediate stack structure MS. The active semiconductor layer ACTL and the sacrificial semiconductor layer SCL may be formed of a material having different etch selectivities from each other. The intermediate stack structure MS may be defined as a stack structure of a dummy semiconductor layer DL and an intermediate sacrificial semiconductor layer MSCL. In some embodiments, the dummy semiconductor layer DL may include the same material as a material of the active semiconductor layer ACTL. The intermediate sacrificial semiconductor layer MSCL may include the same material as a material of the sacrificial semiconductor layer SCL. However, embodiments are not limited thereto.

A dummy gate structure DGS may be formed on the stack structure S_ST. The gate spacer GS may be formed on a side surface of the dummy gate structure DGS.

The stack structure S_ST may be patterned (i.e., selectively removed) using a mask pattern. Accordingly, a plurality of stack structures S_ST patterned in a fin shape may be formed. According to some embodiments, a fin-shaped lower pattern extending in the third direction D3 may be formed on the substrate 100. Further, although it is illustrated that the stack structure S-ST has a constant thickness in the second direction D2, embodiments are not limited thereto, and the stack structure S-ST may have a side surface inclined to have an increasing thickness toward the substrate 100.

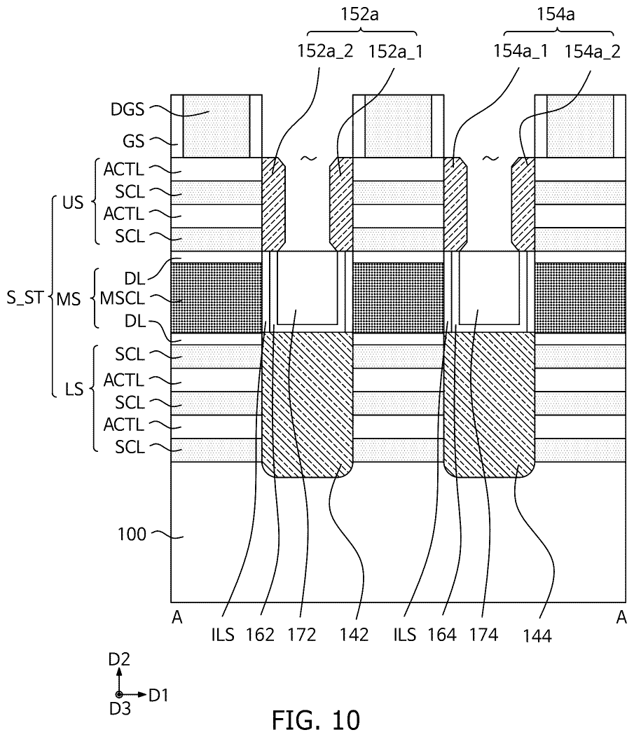

Referring to FIG. 10, the first lower source/drain pattern 142, the first partial growth portion 152a, the second lower source/drain pattern 144, the second partial growth portion 154a, etc., may be formed in a trench formed between the stack structures S_ST. The first lower etch stop film 162 may be formed on the first lower source/drain pattern 142, and the 1-1 intermediate insulating film 172 may be formed on the first lower etch stop film 162. Further, the second lower etch stop film 164 may be formed on the second lower source/drain pattern 144, and the 1-2 intermediate insulating film 174 may be formed on the second lower etch stop film 164. The lower source/drain patterns (e.g., the first lower source/drain pattern 142 and the second lower source/drain pattern 144) may be formed using the epitaxial growth method based on the substrate 100 and the active semiconductor layer ACTL. Although it is illustrated that the lower source/drain patterns (e.g., the first lower source/drain pattern 142 and the second lower source/drain pattern 144) are single films, embodiments are not limited thereto, and they may include a plurality of films.

In some embodiments, the interlayer spacer ILS may be disposed between the intermediate stack structure MS and the lower etch stop films (e.g., the first lower etch stop film 162 and the second lower etch stop film 164).

The first partial growth portion 152a may be formed on the 1-1 intermediate insulating film 172. The second partial growth portion 154a may be formed on the 1-2 intermediate insulating film 174. The first partial growth portion 152a and the second partial growth portion 154a may be formed using the epitaxial growth method. The first partial growth portion 152a and the second partial growth portion 154a may be formed on the side surface of the active semiconductor layer ACTL of an adjacent one of the upper stack structures US spaced apart in the first direction D1 by using the epitaxial growth method.

Each of the 1-1 partial growth portion 152a_1 and the 1-2 partial growth portion 152a_2 of the first partial growth portion 152a may be formed by being epitaxially growing on the side surfaces of the active semiconductor layer ACTL of different ones of the upper stack structures US, respectively. In this case, the 1-1 partial growth portion 152a_1 and the 1-2 partial growth portion 152a_2 of the first partial growth portion 152a may not be connected to each other. Similarly, each of the 2-1 partial growth portion 154a_1 and the 2-2 partial growth portion 154a_2 of the second partial growth portion 154a may be formed by being epitaxially growing on the side surfaces of the active semiconductor layer ACTL of different ones of the stacked upper structures US. In this case, the 2-1 partial growth portion 154a_1 and the 2-2 partial growth portion 154a_2 of the second partial growth portion 154a may not be connected to each other.

Referring to FIG. 11, the first additional growth portion 152b, the second additional growth portion 152b, the first upper etch stop film 182, the second upper etch stop film 184, the 2-1 intermediate insulating film 192, the 2-2 intermediate insulating film 194, the gate electrodes (e.g., the lower gate electrode 122 and the upper gate electrode 124), the gate insulating film 130, the level isolation insulating film SL, etc., may be formed.

The first additional growth portion 152b may be formed between the 1-1 partial growth portion 152a_1 and the 1-2 partial growth portion 152a_2 of the first partial growth portion 152a. The first additional growth portion 152b may be formed using the epitaxial growth method. For example, the first additional growth portion 152b may be formed on the first partial growth portion 152a using the epitaxial growth method. Accordingly, the first upper source/drain pattern 152 including the first partial growth portion 152a and the first additional growth portion 152b may be formed.

The second additional growth portion 154b may be formed between the 2-1 partial growth portion 154a_1 and the 2-2 partial growth portion 154a_2 of the second partial growth portion 154a. The second additional growth portion 154b may be formed using the epitaxial growth method. For example, the second additional growth portion 154b may be formed on the second partial growth portion 154a using the epitaxial growth method. Accordingly, the second upper source/drain pattern 154 including the second partial growth portion 154a and the second additional growth portion 154b may be formed.

The first upper etch stop film 182 may be formed on the first upper source/drain pattern 152. Further, the second upper etch stop film 184 may be formed on the second upper source/drain pattern 154. The 2-1 intermediate insulating film 192 may be formed on the first upper etch stop film 182. Further, the 2-2 intermediate insulating film 194 may be formed on the second upper etch stop film 184.

The sacrificial semiconductor layer SCL and the dummy gate structure DGS on the stack structure S_ST may be removed, and the gate electrodes (e.g., the lower gate electrode 122 and the upper gate electrode 124) and the gate insulating film 130 surrounding the gate electrodes (e.g., the lower gate electrode 122 and the upper gate electrode 124) may be formed. The intermediate sacrificial semiconductor layer MSCL and the dummy semiconductor layer DL of the intermediate stack structure MS may be removed, and the level isolation insulating film SL may be formed. The gate capping pattern GP may be formed on upper regions of the gate electrodes (e.g., the lower gate electrode 122 and the upper gate electrode 124).

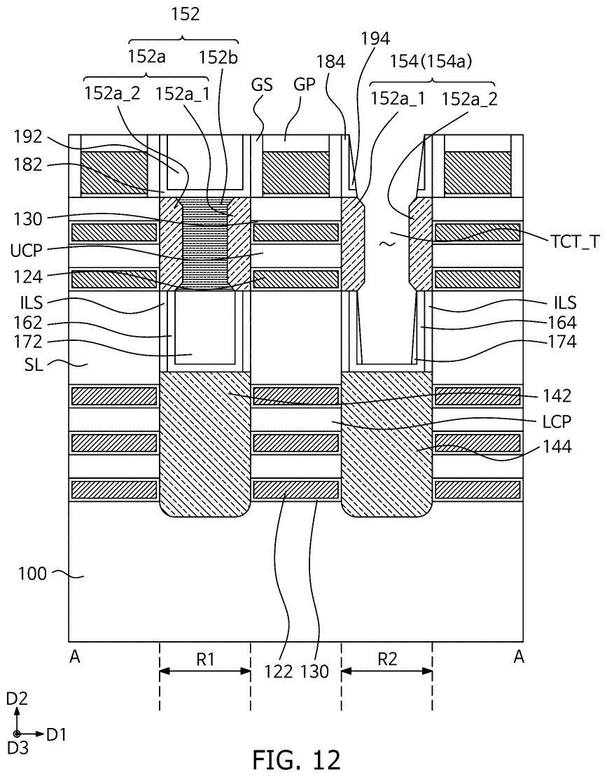

Referring to FIG. 12, a through contact trench TCT_T may be formed on the second region R2 of the substrate 100 to form a through contact (e.g., a through contact TCT of FIG. 2). The 2-2 intermediate insulating film 194 may be selectively removed. The second additional growth portion 154b of the second upper source/drain pattern 154 may be selectively removed. The second additional growth portion 154b may include a material having etch selectivity with respect to the second partial growth portion 154a. For example, the second additional growth portion 154b may include phosphorus-doped silicon germanium (SiGe; P). However, embodiments are not limited thereto. The 1-2 intermediate insulating film 174 may be selectively removed. In some embodiments, the 2-2 intermediate insulating film 194, the second additional growth portion 154b, and the 1-2 intermediate insulating film 174 may be removed at once. As a result, the through contact trench TCT_T may be formed.

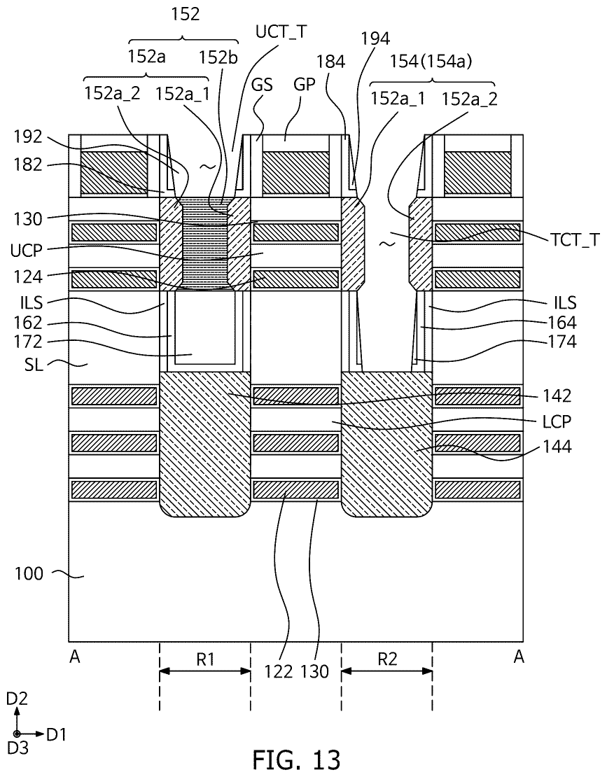

Referring to FIG. 13, an upper source/drain contact trench UCT_T may be formed on the first region R1 of the substrate 100 to form an upper source/drain contact (e.g., upper source/drain contact trench UCT of FIG. 2). In this case, an etching process for the through contact trench TCT_T on the second region R2 may be performed simultaneously. Accordingly, at least a portion of the second lower etch stop film 164 disposed on an upper surface of the second lower source/drain pattern 144 may be removed.

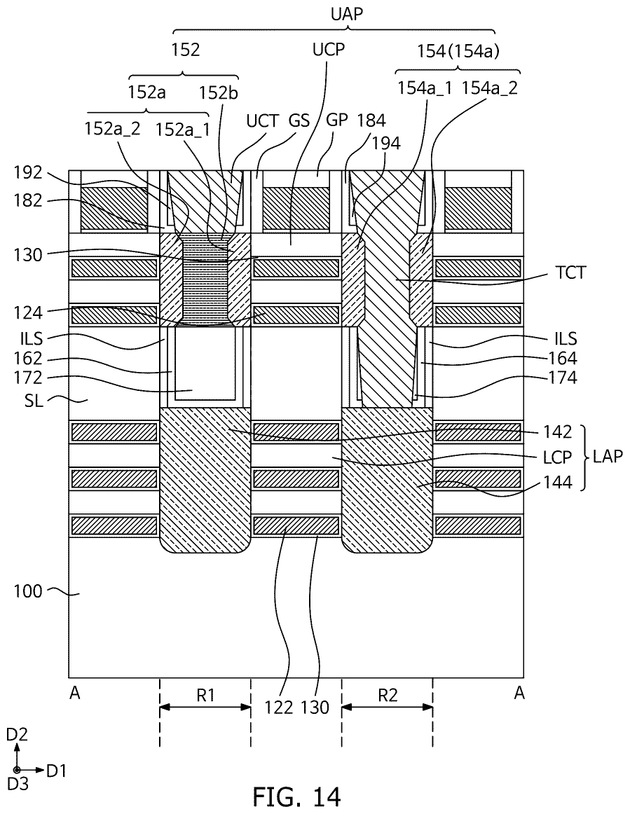

Referring to FIG. 14, the upper source/drain contact UCT electrically connected to the first upper source/drain pattern 152 may be formed by filling the interior of the upper source/drain contact trench UCT_T on the first region R1 of the substrate 100 with a conductive material. Further, the through contact TCT electrically connected to the second upper source/drain pattern 154 and the second lower source/drain pattern 144 may be formed by filling the interior of the through contact trench TCT_T on the second region R2 of the substrate 100.

Through the manufacturing method described above, the semiconductor device described with reference to FIGS. 1 to 8 may be provided. For a semiconductor device according to some embodiments of the present disclosure, it is possible to simplify a patterning process for contact formation by forming a through contact connecting the upper source/drain pattern and the lower source/drain pattern through a process of selectively removing some of the upper source/drain patterns. Further, the risk of deterioration of the semiconductor device can be reduced by removing the oxide film formation step when forming a trench for the through contact. Accordingly, an electrically improved semiconductor device can be provided.

Although non-limiting example embodiments of the present disclosure have been described above with reference to the accompanying drawings, embodiments of the present disclosure are not limited thereto, and various changes and modifications can be made without departing from the spirit and scope of the present disclosure.

What is claimed is:

1. A semiconductor device, comprising:
a lower active pattern extending in a first direction and comprising:
a lower channel pattern;
a first lower source/drain pattern on a first side of the lower channel pattern; and
a second lower source/drain pattern on a second side of the lower channel pattern, opposite to the first side of the lower channel pattern;
an upper active pattern spaced apart from the lower active pattern in a second direction intersecting the first direction and comprising:
an upper channel pattern;
a first upper source/drain pattern on a first side of the upper channel pattern; and
a second upper source/drain pattern on a second side of the upper channel pattern, opposite to the first side of the upper channel pattern; and
a through contact extending through the second upper source/drain pattern in the second direction and electrically connected to the second upper source/drain pattern and the second lower source/drain pattern,
wherein the first upper source/drain pattern comprises:
a first partial growth portion comprising a 1-1 partial growth portion and a 1-2 partial growth portion spaced apart from each other in the first direction; and
an additional growth portion between the 1-1 partial growth portion and the 1-2 partial growth portion,
wherein the second upper source/drain pattern comprises a second partial growth portion comprising a 2-1 partial growth portion and a 2-2 partial growth portion spaced apart from each other in the first direction, and
wherein at least a portion of a side surface of the through contact extends in the second direction along a profile of the second partial growth portion.

2. The semiconductor device according to claim 1, wherein
each of the first partial growth portion and the second partial growth portion comprises a first material, and
the additional growth portion comprises a second material having etch selectivity with respect to the first material.

3. The semiconductor device according to claim 2, wherein the second material is n-type doped silicon germanium.

4. The semiconductor device according to claim 1, wherein a thickness of the first partial growth portion in the first direction decreases towards at least one from among an upper end and a lower end of the first partial growth portion.

5. The semiconductor device according to claim 1, wherein a thickness of the second partial growth portion in the first direction decreases towards at least one from among an upper end and a lower end of the second partial growth portion.

6. The semiconductor device according to claim 1, wherein, at a vertical level of the second upper source/drain pattern, a width of the through contact in the first direction increases towards at least one of from among an upper end and a lower end of the second partial growth portion.

7. The semiconductor device according to claim 1, further comprising an upper source/drain contact above the first upper source/drain pattern and electrically connected to the first upper source/drain pattern.

8. The semiconductor device according to claim 1, further comprising gate electrodes surrounding the lower channel pattern and the upper channel pattern.

9. The semiconductor device according to claim 8, wherein the gate electrodes comprise:
a lower gate electrode surrounding the lower channel pattern; and
an upper gate electrode surrounding the upper channel pattern.

10. The semiconductor device according to claim 1, wherein
the first upper source/drain pattern and the second upper source/drain pattern have an n-type conductivity, and
the first lower source/drain pattern and the second lower source/drain pattern have a p-type conductivity.

11. A semiconductor device, comprising:
a lower active pattern extending in a first direction and comprising:
a lower channel pattern; and
a lower source/drain pattern on at least one side of the lower channel pattern;
an upper active pattern spaced apart from the lower active pattern in a second direction intersecting the first direction and comprising:
an upper channel pattern; and
an upper source/drain pattern on at least one side of the upper channel pattern;
a first intermediate insulating film between the lower source/drain pattern and the upper source/drain pattern;
a through contact extending through the upper source/drain pattern and the first intermediate insulating film in the second direction and electrically connected to the upper source/drain pattern and the lower source/drain pattern; and
an upper etch stop film in contact with at least a portion of a side surface of the through contact.

12. The semiconductor device according to claim 11, wherein a vertical level of the upper etch stop film is lower than or equal to a vertical level of the upper source/drain pattern.

13. The semiconductor device according to claim 11, further comprising a second intermediate insulating film on the first intermediate insulating film,
wherein the upper etch stop film is between the first intermediate insulating film and the second intermediate insulating film.

14. The semiconductor device according to claim 13, wherein the through contact comprises:
a first contact region formed through an upper surface of the second intermediate insulating film and at a vertical level higher than a vertical level of the upper source/drain pattern;
a second contact region in contact with the upper source/drain pattern and at a same vertical level as the vertical level of the upper source/drain pattern; and
a third contact region in contact with the lower source/drain pattern and at a vertical level lower than the vertical level of the upper source/drain pattern.

15. The semiconductor device according to claim 14, wherein a width of the first contact region in the first direction decreases towards a lower end of the first contact region.

16. The semiconductor device according to claim 14, wherein a width of the second contact region in the first direction increases towards at least one from among an upper end and a lower end of the second contact region.

17. The semiconductor device according to claim 14, wherein a width of the third contact region in the first direction decreases towards a lower end of the third contact region.

18. The semiconductor device according to claim 14, wherein the through contact comprises a stepped surface defined by a difference between a width in the first direction of a lower surface of the first contact region and a width in the first direction of an upper surface of the second contact region.

19. The semiconductor device according to claim 14, wherein the through contact comprises a stepped surface defined by a difference between a width in the first direction of a lower surface of the second contact region and a width in the first direction of an upper surface of the third contact region.

20. A semiconductor device, comprising:
a lower active pattern extending in a first direction and comprising:
a lower channel pattern;
a first lower source/drain pattern on a first side of the lower channel pattern; and
a second lower source/drain pattern on a second side of the lower channel pattern, opposite to the first side of the lower channel pattern;
an upper active pattern spaced apart from the lower active pattern in a second direction intersecting the first direction and comprising:
an upper channel pattern;
a first upper source/drain pattern on a first side of the upper channel pattern; and
a second upper source/drain pattern on a second side of the upper channel pattern, opposite to the first side of the upper channel pattern;
a first intermediate insulating film between the second lower source/drain pattern and the second upper source/drain pattern;
a second intermediate insulating film on the first intermediate insulating film;
a through contact extending through the second intermediate insulating film, the second upper source/drain pattern, and the first intermediate insulating film in the second direction and electrically connected to the second upper source/drain pattern and the second lower source/drain pattern; and
an upper etch stop film in contact with at least a first portion of a side surface of the through contact,
wherein the first upper source/drain pattern comprises:
a first partial growth portion comprising a 1-1 partial growth portion and a 1-2 partial growth portion spaced apart from each other in the first direction; and
an additional growth portion between the 1-1 partial growth portion and the 1-2 partial growth portion,
wherein the second upper source/drain pattern comprises a second partial growth portion comprising a 2-1 partial growth portion and a 2-2 partial growth portion spaced apart from each other in the first direction, and
wherein at least a second portion of the side surface of the through contact extends in the second direction along a profile of the second partial growth portion.
